(19) United States
(12) Patent Application Publication
(10) Pub. No.: US 2020/0166414 A1
(43) Pub. Date: May 28, 2020

(54) METHOD

(71) Applicant: JOHNSON MATTHEY PUBLIC LIMITED COMPANY, London (GB)

(72) Inventor: Roger WILKINSON, Hertfordshire (GB)

(21) Appl. No.: 16/331,158

(22) PCT Filed: Sep. 7, 2017
(86) PCT No.: PCT/GB2017/052609

§ 371 Date: Mar. 7, 2019

(30) Foreign Application Priority Data
Sep. 8, 2016 (GB) 1615272.0

(51) Int. Cl. G01K 7/14; H01L 35/20

(52) U.S. Cl. CPC G01K 7/14; H01L 35/20

(57) ABSTRACT

The present invention relates to a Pt vs. RhPt thermocouple (such as a Type R or Type S thermocouple), and to the modification of the electrical properties of the same, while in service. More especially there is provided a method for reducing the drift of a Pt vs. RhPt thermocouple while the thermocouple is in use in an oxidising environment, wherein the Pt limb of the thermocouple is doped platinum comprising an effective amount of one or more dopants selected from the group consisting of yttrium, zirconium and samarium.

### FIELD OF THE INVENTION

The present invention concerns Pt vs. RhPt thermocouples, in particular the modification of the electrical properties of a Pt vs. RhPt thermocouple while in service.

### BACKGROUND

A thermocouple is used to measure the temperature of an environment, often over long periods of time and at constant temperature. Pure platinum (Pt) is used as the negative limb of Type R and Type S thermocouples. Very pure platinum is weak at high temperatures and is often the cause of thermocouple open circuit failure. While introducing metallic alloying elements into the Pt limb may decrease the likelihood of Pt limb failure, the metallic alloying elements can adversely affect the electrical properties of the thermocouple.

One source of error in thermocouple measurement is drift, where the acquired voltage changes over time from the expected value despite the temperature remaining substantially constant. Drift is generally caused by contamination of the Pt limb. Contamination can be built in, acquired in service or originate from the thermocouple's rhodium-platinum alloy (RhPt alloy) limb.

Rhodium drift (also known as “migration”) is the transfer of rhodium (Rh) from the RhPT alloy limb to the Pt limb. The metal transfer is possible because Rh oxide is volatile above 1200° C. and the gas diffuses or convects to cooler areas where it condenses. Rhodium oxide is not very stable and, once it dissociates, the Rh metal contaminates the Pt limb. Rh oxide can often be seen as a black layer covering the alloy limb.

EP2778639A (to Tanaka Kikinzoku Kogyo K. K.) describes a Pt vs. Pt—Rh based thermocouple wherein the Pt wire contains a zirconium (Zr) oxide in an amount of 0.02 to 0.5 mass % in terms of Zr dispersed in the Pt wire. The Pt wire is prepared by introducing a dispersion of electrically neutral zirconia particles into Pt powder by wet ball milling in a zirconia container, using zirconia balls. The wire, once made, is ultimately treated for 3 hours at 1700° C. to ensure full oxidation of the zirconia and restore the electrical properties of the wire. EP2778639A neither discloses nor suggests how to minimise drift over the lifetime of a thermocouple whilst in service.

U.S. Pat. No. 3,696,502 (to Johnson Matthey & Company Limited) described a method for making dispersion strengthened metals or alloys.

### DESCRIPTION OF THE INVENTION

The present invention seeks to overcome the disadvantages associated with prior art thermocouples. The invention provides a method for achieving substantially consistent and reliable readings from a Pt vs. RhPt thermocouple over its service life. In certain embodiments, the invention provides a method for prolonging the service life of a Pt vs. RhPt thermocouple.

In one aspect, the present invention provides a method for reducing the drift of a Pt vs. RhPt thermocouple while the thermocouple is in use in an oxidising environment, wherein:
the Pt limb of the thermocouple is doped platinum comprising:
   (a) platinum; and
   (b) an effective amount of one or more dopants selected from the group consisting of yttrium, zirconium and samarium.

It will be understood that whilst the amounts of each element are given assuming that the main metal is pure platinum, in practical terms, the platinum and dopants may contain impurities at levels which would be normally expected for such metals.

While each element or combination of elements in a limb of the thermocouple may be expressed as a range, the total weight percent (wt %) of the elements in the limb adds up 100 wt %.

The Pt limb of the thermocouple is doped platinum. “Doped” refers to the intentional introduction of an effective amount of the micro-alloying metallic elements yttrium, zirconium and/or samarium into thermocouple grade platinum. “Doping” and “dopant” are construed accordingly.

An “effective amount” of one or more of the dopants can and will vary according to the dopant used. In general, an “effective amount” means the amount of the dopant needed to achieve a detectable or observable reduction in drift of the thermocouple while in service in an oxidising atmosphere.

The platinum to which the dopant is added may be thermocouple grade platinum, e.g. ≥99.997 wt % pure, such as ≥99.999 wt % pure.

The doped platinum comprises one or more dopants selected from the group consisting of yttrium, zirconium and samarium, preferably zirconium. Without wishing to be bound by theory, it is believed that the inclusion of these elements (in particular zirconium) actively counter the effect of rhodium drift through their oxidation to yttrium oxide, zirconium oxide or samarium oxide. Rhodium drift causes the negative Pt limb to become more positive in use but, as a result of the oxidation of yttrium, zirconium and/or samarium, the Pt limb of the thermocouple does not become as positive as quickly. The thermocouple of the invention, therefore, experiences drift but it is opposite to that caused by rhodium drift, thus counteracting the effects of the undesirable rhodium drift. This is in contrast with prior art thermocouples, such as those described by Tanaka in EP2778639A as Tanaka purport that the thermocouple in that instance does not experience drift for practical purposes.

The doped platinum may comprise any suitable amount of the dopants, such as about 0.001 to about 0.01 wt % (e.g. about 0.0025 to about 0.0075 wt %) each of any one or more dopants selected from the group consisting of yttrium, zirconium and samarium. The doped platinum may comprise ≥about 0.0015 wt %, ≥about 0.0025 wt %, or ≥about 0.005 wt % each of any one or more dopants selected from the group consisting of yttrium, zirconium and samarium. The doped platinum may comprise ≤about 0.01 wt % ≤about 0.009 wt %, ≤about 0.008 wt %, ≤about 0.007 wt %, ≤about 0.006 wt %, or ≤about 0.005 wt % each of any one or more dopants selected from the group consisting of yttrium, zirconium and samarium.

In one embodiment, the doped platinum may comprise about 0.0025 to about 0.0075 wt % of zirconium. The doped platinum may comprise ≥about 0.0025 wt %, ≥about 0.003 wt %, ≥about 0.0035 wt %, ≥about 0.004 wt % or ≥about 0.0045 wt % of zirconium. The doped platinum may comprise ≤about 0.0075 wt %, ≤about 0.007 wt %, ≤about 0.0065 wt %, ≤about 0.006 wt %, ≤about 0.0055 wt % of zirconium. In one embodiment, the doped platinum comprises about 0.005 wt % of zirconium.

In one embodiment, the doped platinum may comprise about 0.0025 to about 0.0075 wt % of yttrium. The doped platinum may comprise ≥about 0.0025 wt %, ≥about 0.003 wt %, ≥about 0.0035 wt %, ≥about 0.004 wt % or ≥about 0.0045 wt % of yttrium. The doped platinum may comprise ≤about 0.0075 wt %, ≤about 0.007 wt %, ≤about 0.0065 wt %, ≤about 0.006 wt %, ≤about 0.0055 wt % of yttrium. In one embodiment, the doped platinum comprises about 0.005 wt % of yttrium.

In one embodiment, the doped platinum may comprise about 0.0025 to about 0.0075 wt % of samarium. The doped platinum may comprise ≥about 0.0025 wt %, ≥about 0.003 wt %, ≥about 0.0035 wt % or ≥about 0.004 wt % or ≥about 0.0045 wt % of samarium. The doped platinum may comprise ≤about 0.0075 wt %, ≤about 0.007 wt %, ≤about 0.0065 wt %, ≤about 0.006 wt %, ≤about 0.0055 wt % of samarium. In one embodiment, the doped platinum comprises about 0.005 wt % of samarium.

The thermocouple is used in an oxidising atmosphere, for example, an atmosphere comprising oxygen, NOx (i.e. oxides of nitrogen) or a combination thereof. In one preferred embodiment, the atmosphere comprises oxygen (for example, air).

The doped platinum may further comprise:
(c) an effective amount of one or more oxides selected from the group consisting of yttrium oxide, zirconium oxide and samarium oxide.

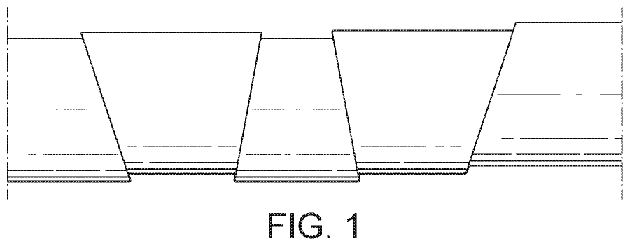

Failure of a thermocouple can be due to grain growth where single grains grow at the expense of others and may eventually occupy the entire diameter of the wire leading to a “bamboo structure” (see FIG. 1). The bamboo structure can make the wire weaker as the stress to cause slip in a single grain is lower than across multiple grains. In addition, the boundaries between grains can be a source of weakness both from contamination, slip and from diffusional or creep processes at high temperature which cause voids to form and eventually separation or fracture of the wire.

An “effective amount” of one or more oxides therefore means the amount of the oxide needed to reduce grain growth in the Pt limb. An “effective amount” of one or more of the oxides can and will vary according to the oxide used.

The oxide may be added to the platinum during manufacture of the doped platinum. Alternatively, the oxide may be formed in situ by partially oxidising a dopant (e.g. zirconium) during the manufacture of the doped platinum. Regardless of the method by which the oxide is incorporated, the yttrium oxide, zirconium oxide or samarium oxide is present in addition to any dopant which is converted in use of the thermocouple to the corresponding dopant oxide.

In one embodiment, the oxide is yttrium oxide. In another embodiment, the oxide is zirconium oxide. In yet another embodiment, the oxide is samarium oxide.

The doped platinum may comprise any suitable amount of the oxides, such as about 0.001 to about 0.01 wt % (e.g. about 0.0025 to about 0.0075 wt %) each of any one or more oxides selected from the group consisting of yttrium oxide, zirconium oxide and samarium oxide. The doped platinum may comprise ≥about 0.0015 wt %, ≥about 0.0025 wt %, or ≥about 0.005 wt % each of any one or more oxides selected from the group consisting of yttrium oxide, zirconium oxide and samarium oxide. The doped platinum may comprise ≤about 0.01 wt % ≤about 0.009 wt %, ≤about 0.008 wt %, ≤about 0.007 wt %, ≤about 0.006 wt %, or ≤about 0.005 wt % each of any one or more oxides selected from the group consisting of yttrium oxide, zirconium oxide and samarium oxide.

In one embodiment, the doped platinum may comprise about 0.0025 to about 0.0075 wt % of zirconium oxide. The doped platinum may comprise ≥about 0.0025 wt %, ≥about 0.003 wt %, ≥about 0.0035 wt %, ≥about 0.004 wt % or ≥about 0.0045 wt % of zirconium oxide. The doped platinum may comprise ≤about 0.0075 wt %, ≤about 0.007 wt %, ≤about 0.0065 wt %, ≤about 0.006 wt %, ≤about 0.0055 wt % of zirconium oxide. In one embodiment, the doped platinum comprises about 0.005 wt % of zirconium oxide.

In one embodiment, the doped platinum may comprise about 0.0025 to about 0.0075 wt % of yttrium oxide. The doped platinum may comprise ≥about 0.0025 wt %, ≥about 0.003 wt %, ≥about 0.0035 wt %, ≥about 0.004 wt % or ≥about 0.0045 wt % of yttrium oxide. The doped platinum may comprise ≤about 0.0075 wt %, ≤about 0.007 wt %, ≤about 0.0065 wt %, ≤about 0.006 wt %, ≤about 0.0055 wt % of yttrium oxide. In one embodiment, the doped platinum comprises about 0.005 wt % of yttrium oxide.

In one embodiment, the doped platinum may comprise about 0.0025 to about 0.0075 wt % of samarium oxide. The doped platinum may comprise ≥about 0.0025 wt %, ≥about 0.003 wt %, ≥about 0.0035 wt %, ≥about 0.004 wt % or ≥about 0.0045 wt % of samarium oxide. The doped platinum may comprise ≤about 0.0075 wt %, ≤about 0.007 wt %, ≤about 0.0065 wt %, ≤about 0.006 wt %, ≤about 0.0055 wt % of samarium oxide. In one embodiment, the doped platinum comprises about 0.005 wt % of samarium oxide.

The invention will now be described by way of the following non-limiting Examples and with reference to the following FIGURE in which:

FIG. 1 illustrates a bamboo structure resulting from grain growth in a 0.5 mm diameter pure Pt wire from a failed Pt limb.

### EXAMPLE

### Example 1

### Preparation of the Pt Limb

The example is produced by partially oxidizing an alloy of platinum and zirconium to give both metallic zirconium and oxidized zirconium in the platinum.

The alloy contains approximately 100 ppm by weight of zirconium prior to partial oxidation. 0.6 g of zirconium is added to 6.5 kg of high purity platinum (99.997 wt % pure); 92 ppm by weight of zirconium was added.

The platinum used is of thermocouple quality. It is analysed before alloying with zirconium and is found to contain 33 ppm by weight of impurities by direct measurement). The emf output of the platinum before alloying with zirconium is measured in comparison with NIST SRM 1967a Pt reference material (0 μV) and is found to be between 8 μV and 10 μV at approximately 1064° C. and between 15 μV and 18 μV at approximately 1554° C.

The alloy is melted under a reduced pressure protective atmosphere of inert gas to prevent oxidation of the zirconium. The resulting ingot is hot forged, cold rolled and drawn to form wire. The wire is flame sprayed to form a slab of partially bonded flakes with porosity between the flakes; this provides a continuous but fragile structure. Some zirconium oxidation occurs during the spraying process.

The slab is heated in air to promote further but not total oxidation. The slab is compacted to a fully dense bar by hot forging. The bar is cold rolled and drawn to a 0.5 mm diameter wire.

After annealing using electrical resistive heating to heat the wire to 1100° C. for 10 minutes the emf output of the wire is measured in comparison with NIST SRM 1967a and found to be 32 μV at approximately 1064° C. and between 53 μV and 54 μV at approximately 1554° C.

### Example 2

### Positive Drift

A sample of the wire prepared according to Example 1 is heated in air in an electric furnace at 1200° C. for 140 hours to simulate service conditions. The wire is again measured in comparison with NIST SRM 1967a and the output is 27 μV at approximately 1064° C. and 49 μV at approximately 1554° C.

A reduction in output of the Pt limb in a thermocouple comprising Pt and 10% RhPt (Type S) or Pt and 13% RhPt (Type R) increases the indicated temperature of the thermocouple. The measured reduction in the emf of the Pt limb equates to a 0.4° C. increase in the indicated temperature of a Type R or Type S thermocouple at both the test temperatures.

The output of a sample of the wire prepared according to Example 1 is measured before and after heating at 1200° C. in air for 140 hours:

| | | |
|---|---|---|
| Before | After | Change |

| Temperature | (μV) | (μV) | (μV) | (° C.) |
|---|---|---|---|---|
| Approximately 1064° C. | 32 | 27 | 5 | 0.4 |
| Approximately 1554° C. | 54 | 49 | 5 | 0.4 |

Without wishing to be bound by theory, the measured reduction in the Pt limb output relative to pure Pt reference material is significant because the Pt limb of a thermocouple normally becomes increasingly contaminated in use with metallic impurities both from the local environment and from the RhPt alloy thermocouple limb (referred to as Rh migration or Rh drift). The observed effect acts to counter the normal drift.

The reduction in output has been caused by the further oxidation of metallic zirconium in the wire. Increasing the level of metallic contamination in the Pt limb always reduces the temperature indicated by the thermocouple. In contrast adding oxide inclusions to Pt does not change the emf output by the same amount and the effect of adding ZrO₂ may be negligible. Converting metallic zirconium to oxidized zirconium in use therefore acts to reduce the emf output of the Pt and compensate for other acquired contamination.

Compensating for normal downward drift in the thermocouple indicated temperature is important because otherwise the drift would be greater and the thermocouple would have a shorter service life.

1. A method for reducing the drift of a Pt vs. RhPt thermocouple while the thermocouple is in use in an oxidizing environment, wherein:
the Pt limb of the thermocouple is doped platinum comprising:
(a) platinum; and
(b) an effective amount of one or more dopants selected from the group consisting of yttrium, zirconium and samarium.

2. A method according to claim 1, wherein the platinum to which the dopant is added is ≥99.997 wt % pure.

3. The method according to claim 2, wherein the platinum is ≥99.999 wt % pure.

4. The method according to claim 1, wherein the doped platinum comprises about 0.001 to about 0.01 wt % each of any one or more dopants selected from the group consisting of yttrium, zirconium and samarium.

5. The method according to claim 1, wherein the dopant is zirconium.

6. The method according to claim 4, wherein the doped platinum comprises about 0.0025 to about 0.0075 wt % of zirconium.

7. The method according to claim 1, wherein the oxidizing atmosphere comprises oxygen, NOx or a combination thereof.

8. The method according to claim 1, wherein the doped platinum further comprises:
(c) an effective amount of one or more oxides selected from the group consisting of yttrium oxide, zirconium oxide and samarium oxide.

9. The method according to claim 8, wherein the doped platinum comprises about 0.001 to about 0.01 wt % each of any one or more oxides selected from the group consisting of yttrium oxide, zirconium oxide and samarium oxide.

10. The method according to claim 8, wherein the oxide is zirconium oxide.

11. The method according to claim 10, wherein the doped platinum comprises about 0.0025 to about 0.0075 wt % of zirconium oxide.
